(19) United States
(12) Patent Application Publication
(10) Pub. No.: US 2007/0019494 A1
(43) Pub. Date: Jan. 25, 2007

(54) Semiconductor memory module with bus architecture

(76) Inventors: Karl-Heinz Moosrainer, Munchen (DE); Martin Benisek, Munchen (DE); Srdjan Djordjevic, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/483,174

(22) Filed: Jul. 10, 2006

(30) Foreign Application Priority Data
Jul. 8, 2005 (DE) 102005032059.7

(51) Int. Cl. G11C 8/00

(52) U.S. Cl. 365/230.03

(57) ABSTRACT

A semiconductor memory module comprises a control chip that drives various memory chips on a circuit board. The memory chips are connected to the control chip via a control clock bus in a loop fly-by topology. The memory chips are arranged on the module circuit board in such a way that memory chips of different ranks are in connected to the control clock bus alongside one another. A data clock bus for carrying a data clock signal connects a memory chip of different ranks to the control chip in each case in accordance with a point-to-point topology. The semiconductor memory module enables the propagation time of a control clock signal on the control clock bus to be adapted to the propagation time of the data clock signal on the data clock bus.

### CROSS REFERENCE TO RELATED APPLICATIONS

This application claims priority under 35 USC §119 to German Application No. DE 10 2005 032059.7, filed on Jul. 8, 2005, and titled “Semiconductor Memory Module with Bus Architecture,” the entire contents of which are hereby incorporated by reference.

### FIELD OF THE INVENTION

The present invention relates to a semiconductor memory module in which a control chip is connected to a plurality of memory chips via various buses.

### BACKGROUND OF THE INVENTION

FIG. 1 shows a cross section of a module circuit board MP of a semiconductor memory module. A plurality of memory components CB are arranged on the left and on the right of a control component SB on the top side and underside of the module circuit board. A memory chip U is situated within each of the memory components CB. Memory components comprising the memory chips U1, U2, U3 and U4 are situated on the left of the control component SB in a row on a top side of the module circuit board. Memory components comprising the memory chips U10, U11, U12 and U13 are arranged on the left-hand side of the module circuit board on the underside of the module circuit board. The housing of the memory components is embodied as a fine pitch ball grid array package FBGA, by way of example. The control component SB contains an internal control chip, such as a hub chip. The housing of the control component is likewise embodied as a fine pitch ball grid array package in the example of FIG. 1.

The module circuit board MP is embodied as a multilayer module circuit board having a plurality of layers L1, . . . , Ln. The control component SB is connected to the memory components via various bus systems for the driving the individual memory components CB. FIG. 1 illustrates a control clock bus CLKB1 and a control clock bus CLKB2 as representative of the various buses. The control clock bus CLKB1 runs in a layer L1 of the module circuit board and from there connects the hub chip of the control component SB to the memory chips U1, U2, U3 and U4. The control clock bus CLKB2 is used for connecting the memory chips U10, U11, U12 and U13 on the underside of the module circuit board. The control clock bus CLKB2 is routed, proceeding from the hub chip, through the module circuit board as far as a layer Ln near to the underside of the module circuit board. From there it runs further along the layer Ln and connects the memory chips U10, U11, U12 and U13 on the underside of the module circuit board to the hub chip.

FIG. 2A shows the top side of the module circuit board MP in a plan view. The control chip SC of the control component SB and the individual memory chips U1, . . . , U27 of the memory components are illustrated. The memory chips are arranged in two rows on the module circuit board. On the left-hand side of the control chip SC, the memory chips U1, . . . , U4 as shown in FIG. 1 are arranged in a lower row and further memory chips U5, . . . , U9 are arranged in an upper row. On the right-hand side of the control chip SC, the memory chips U24, . . . , U27 that are likewise shown in FIG. 1 are arranged in the lower row and further memory chips U19, . . . , U23 are arranged in the upper row.

FIG. 2B shows the underside of the module circuit board MP in a plan view. Here, too, the memory chips are arranged in two rows. On the left-hand side of the module circuit board the memory chips U10, . . . , U13 shown in FIG. 1 are arranged in a lower row and further memory chips U14, . . . , U18 are arranged in an upper row. On the right-hand side of the module circuit board, the memory chips U33, . . . , U36 that are likewise illustrated in FIG. 1 are arranged in the lower row and further memory chips U28, . . . , U32 are arranged in the upper row.

The memory chips are not driven directly externally, but rather communicate with the external environment of the semiconductor memory module via the control chip SC. For this purpose, the control chip SC is connected to an external control component MC (shown in FIG. 2A), for example, a memory controller, via an external access bus B. The memory controller accesses the individual memory chips on the top side of the module circuit board and the memory chips on the underside of the circuit board via the control chip SC.

Situated within each memory chip, as illustrated in FIG. 3, is a memory cell array SZF, in which memory cells SZ are arranged in matrix-like fashion along word lines WL and bit lines BL. In the case of a dynamic random access memory cell, a DRAM memory cell of this type comprises a selection transistor AT and a storage capacitor SC. By means of a corresponding control potential on the word line WL, the memory cell SZ can be connected to the bit line BL for the purpose of writing data in to the storage capacitor SC and reading data out from the storage capacitor SC.

The memory controller drives the control chip SC with control and address signals via the external access bus B in order to access the individual memory cells within the memory cell arrays of the memory chips. Data signals for writing data to the memory chips and for reading out data from the memory chips are likewise transmitted via the external access bus B.

A form of organization of the memory chips specifies how much data can be read out simultaneously from a memory chip in the event of a read access or how much data can be simultaneously written to a memory chip in the event of a write operation. In the case of a ×4 form of organization, by way of example, in the event of a read access to the memory cell array of the memory chip U1, four data signals are output simultaneously, are fed to the control chip SC via a data bus and from there are forwarded to the memory controller MC via the external access bus B. In the case of an ×8 form of organization by way of example, in the event of a read access to the memory cell array of the memory chip U1, eight data signals are simultaneously read out from the memory cells, are fed to the control chip SC via a data bus and from there are forwarded to the memory controller via the external bus.

The number of memory chips from which data can simultaneously be read out in the event of a read access or the number of memory chips to which data can simultaneously be written in the event of a write access is dependent on the form of organization of the memory chips and a data width of the external access bus B. In the case of a ×8 form of organization and a bus width of the external access bus B of 72 bits, by way of example, a read or write access is simultaneously effected to 9 memory chips of the semiconductor memory module. Nine memory chips are therefore combined to form a group, a so-called rank.

With reference again to FIGS. 2A and 2B, in accordance with an industry standard, the memory chips that respectively belong to a specific rank are arranged alongside one another within a row on the module circuit board. Thus, by way of example, on the top side of the module circuit board, the memory chips U1, U2, U3 and U4 in the lower row of the module circuit board and also the memory chips U19, U20, U21, U22 and U23 in the upper row of the module circuit board belong to the rank G1. The memory chips U5, U6, U7, U8 and U9 in the upper row of the module circuit board and the memory chips U24, U25, U26, and U27 in the lower row of the module circuit board belong to a rank G2. On the underside of the module circuit board, the memory chips U10, U11, U12, and U13 and also the memory chips U28, U29, U30, U31 and U32 belong to a rank G3. The memory chips U14, U15, U16, U17, and U18 and also the memory chips U33, U34, U35, and U36 belong to a rank G4. The memory chips U1, . . . , U36 are thus distributed between 4 ranks. The module circuit board shown in FIGS. 2A and 2B therefore corresponds to a 4R×8 module configuration.

In the case of an 8R×8 module configuration, there are twice as many memory chips situated on a module circuit board. In this case, it is likewise possible to use the arrangement of memory chips shown in FIGS. 2A and 2B on the module circuit board MP. In an 8R×8 module configuration, however, there are in each case 2 memory chips arranged in each of the memory components. In this case, a dual stack arrangement of memory chips in each of the memory components would be employed.

The following explanations relate to the memory chips U1, . . . , U18 on the left-hand side of the module circuit board. They may likewise also be applied to the memory chips U19, . . . , U36 on the right-hand side of the module circuit board.

FIG. 4 shows the top side O of the module circuit board and the underside U of the module circuit board MP in a 4R×8 module configuration. The rank assignment is the same as in FIGS. 2A and 2B. The memory chips U1, . . . , U4 of the row R2 belong to the rank G1 and the memory chips U5, . . . , U9 of the row R1 belong to the rank G2. On the underside of the module circuit board, the memory chips U10, . . . , U13 of the row R4 belong to the rank G3 and the memory chips U14, . . . , U18 of the row R3 belong to the rank G4. In order to drive the memory chips with control clock signals CLK and data clock signals DQS, the memory chips are connected to the control chip via various buses.

FIG. 4 illustrates two control clock buses CLKB1 and CLKB2 and two data clock buses DB1 and DB2. A control clock signal CLK1 and a control clock signal CLK2 are transmitted via the control clock buses CLKB1 and CLKB2. Internal control operations, such as turning off selection transistors and controlling them in the on state, proceed synchronously with rising and falling edges of the control clock signals. A data clock signal DQS1 and a data clock signal DQS2 are transmitted via the data clock buses DB1 and DB2, respectively. In the event of read and write access, data are read out from the memory chips and written to the memory chips synchronously with the data clock signals. The buses run on different layers of the module circuit board, as is illustrated in FIG. 1 using the example of the control clock buses CLKB1 and CLKB2.

The memory chips U1, . . . , U9 on the top side of the module circuit board are connected to the control chip SC via the control clock bus CLKB1 for carrying the control clock signal CLK1. The memory chips U10, . . . , U18 on the underside of the module circuit board are connected to the control clock bus CLKB2. The control clock bus CLKB2 is connected to the control chip SC on the top side of the module circuit board via a contact-connecting hole. The two control clock buses are in each case terminated by a terminating impedance T.

The two control clock buses CLKB1 and CLKB2 are embodied in a so-called loop fly-by topology. In this type of topology, the memory chips U1, . . . , U4 and also the memory chips U5, . . . , U9 are arranged along the control clock bus CLKB1 and the memory chips U10, . . . , U13 and also the memory chips U14, . . . , U18 are arranged along the control clock bus CLKB2. In accordance with an industry standard, the memory chips that respectively belong to a rank are arranged alongside one another along the two control clock buses. Accordingly, the memory chips that belong to a rank, as shown in FIG. 4, are also arranged alongside one another within a row on the module circuit board.

Furthermore the control chip SC is connected to the individual memory chips via different data clock buses DB1 and DB2. In accordance with a standardization, as shown in FIG. 4, a respective memory chip of each rank is connected to the control chip via a common data clock bus. In this case, the memory chips are arranged at a respective end of a data clock bus while the control chip is arranged at another end of said data clock bus. The data clock buses are thus embodied in a so-called point-to-point topology in each case.

In FIG. 4, by way of example, the memory chip U1 of the rank G1, the memory chip U8 of the rank G2, the memory chip U10 of the rank G3 and the memory chip U17 of the rank G4 are connected to the control chip SC via the common data clock bus DB1. For this purpose, the data clock bus DB1 branches in a contact-connecting hole VD1 to the memory chips U1 and U8 on the top side of the module circuit board and to the memory chips U10 and U17 on the underside of the module circuit board. The memory chip U2 of the rank G1, the memory chip U7 of the rank G2, the memory chip U11 of the rank G3 and the memory chip U16 of the rank G4 are connected to the control chip SC via the common data clock bus DB2. The remaining memory chips of the four ranks are connected to the control chip via further data clock buses. In this case, in a 4 rank configuration of the semiconductor memory module, a data clock bus in each case connects four memory chips to the control chip, each of the four memory chips belonging to a different rank. The data clock buses have a one-point-to-four-point topology in the example of FIG. 4.

As explained above, the data clock signal DQS1 and the data clock signal DQS2 are transmitted on the data clock buses DB1 and DB2 respectively. In the case of a read access, the data stored in the memory cells of the memory chips are read out synchronously with the data clock signal. In the case of a write access, data are written to the memory cells of the memory chips synchronously with the data clock signal. Furthermore, control operations in the event of read and write accesses, such as, for example, turning off selection transistors of the memory cells and controlling the selection transistors in the on state, within the memory chips are executed synchronously with the control clock signal CLK1 and CLK2 on the control clock buses CLKB1 and CLKB2.

In order to ensure entirely satisfactory operation, in the example of memory chips U1 and U8 for example, it is necessary for the control clock signal CLK1 and the data clock signal DQS1 to reach the two memory chips U1 and U8 virtually at the same time subject to a small deviation of approximately 400 ps. The two signals must be synchronized with one another. Due to the different bus topologies for the data clock bus DB1 and the control clock bus CLKB1, however, different signal propagation times occur on the two buses. The data clock signal DQS1 transmitted via the data clock bus DB1 reaches, for example, the memory chip U1 of the rank G1 and the memory chip U8 of the rank G2 approximately at the same time. On the other hand, due to the small distance between control chip SC and memory chip U1, the control clock signal CLK1 on the control clock bus CLKB1 reaches the memory chip U1 significantly faster than the same control clock signal reaches the memory chip U8 of the rank G2 at the end of the control clock bus CLKB1. Likewise, the control clock signal CLK2 on the underside of the module circuit board reaches the memory chip U10 of the rank G3 significantly faster than the same clock signal reaches the memory chip U17 of the rank G4. On the other hand, the two memory chips U10 and U17 are driven approximately simultaneously by the data clock signal DQS1 since the length of the data clock bus DB1 from the control chip SC to the memory chip U10 is approximately the same as the length of the data clock bus DB1 between the control chip SC and the memory chip U17.

The propagation time difference of the control clock signal CLK1 between the memory chip U1 and the memory chip U8, and the propagation time difference of the control clock signal CLK2 between the memory chip U10 and the memory chip U17 are approximately 1 ns, by way of example. If the data clock bus DB1 is embodied such that the data clock signal DQS1 reaches the memory chip U1 and the memory chip U10 approximately simultaneously with the control clock signal CLK1, then there is also a temporal offset of approximately 1 ns between the data clock signal DQS1 and the control clock signal CLK1 for the memory chips U8 and U17. This problem, described above with respect to memory chips U1, U8, U10 and U17, also applies to the rest of the memory chips.

Thus, what is needed is a semiconductor memory module in which signals that are transmitted from a control chip to a memory chip via different buses reach the memory chip approximately at the same time.

### SUMMARY OF THE INVENTION

Briefly, a semiconductor memory module with a bus architecture is provided. The semiconductor memory module comprises a circuit board and a plurality of memory chips on the circuit board. The plurality of memory chips comprising at least a first group of chips and a second group of chips. A first bus is provided on the module circuit board that transmits a first control signal and a second bus is provided on the module circuit board that transmits a second control signal. A control chip is provided on the circuit board that is connected to the first bus and the second bus. The control chip simultaneously accesses memory chips in the first group or the second group. The plurality of memory chips are connected to the first bus along a length thereof such that a respective one of the memory chips in the first group is connected to the first bus alongside a respective one of the memory chips of the second group.

### BRIEF DESCRIPTION OF THE DRAWINGS

FIG. 1 shows a cross section through a conventional semiconductor memory module.

FIG. 2A shows a plan view of a top side of a module circuit board of a conventional semiconductor memory module with a connected memory controller.

FIG. 2B shows a plan view of an underside of a module circuit board of a conventional semiconductor memory module.

FIG. 3 shows a memory cell array of a memory chip of a conventional semiconductor memory module.

FIG. 4 shows a top side and underside of a module circuit board of a conventional semiconductor memory module with an arrangement of memory chips and control and data clock buses.

FIG. 5 shows a top side and underside of a module circuit board of a semiconductor memory module with an arrangement of memory chips and control and data clock buses in accordance with an embodiment of the invention.

FIG. 6 shows a top side of a module circuit board of a semiconductor memory module with an arrangement of memory chips and a first control clock bus and data clock buses in accordance with an embodiment of the invention.

FIG. 7 shows a top side of a module circuit board of a semiconductor memory module with an arrangement of memory chips and a second control clock bus and data clock buses in accordance with an embodiment of the invention.

FIG. 8 shows a top side and underside of a module circuit board of a semiconductor memory module with an arrangement of memory chips and an address bus in accordance with an embodiment of the invention.

FIG. 9 shows a cross section through a module circuit board with an address bus in accordance with the embodiment shown in FIG. 8.

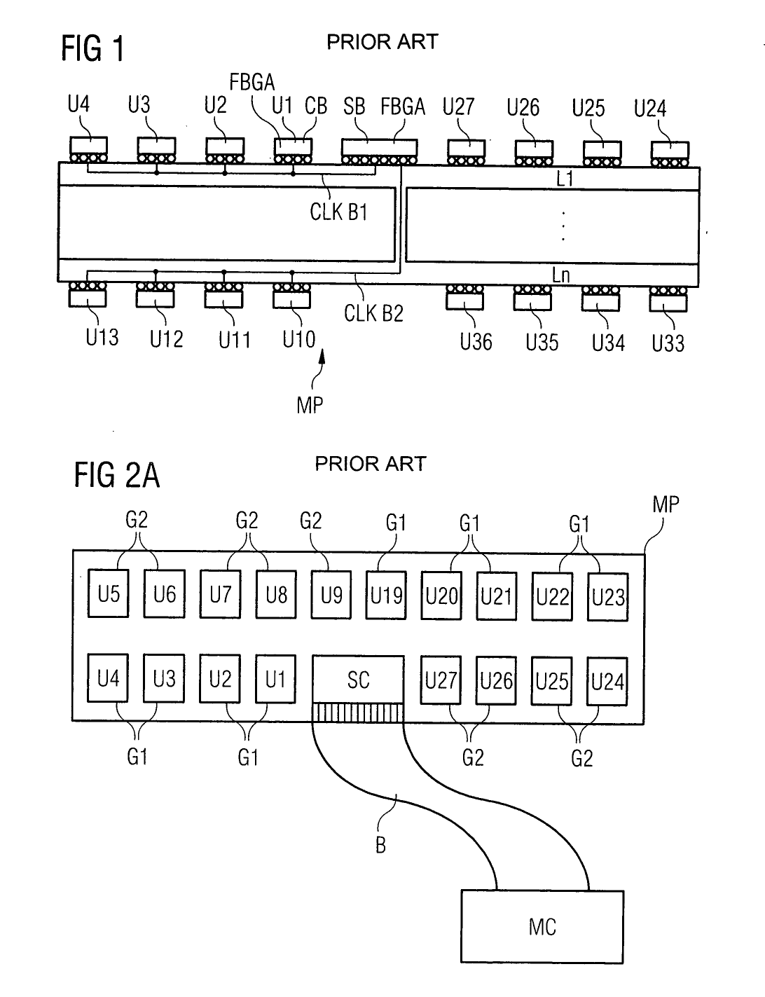

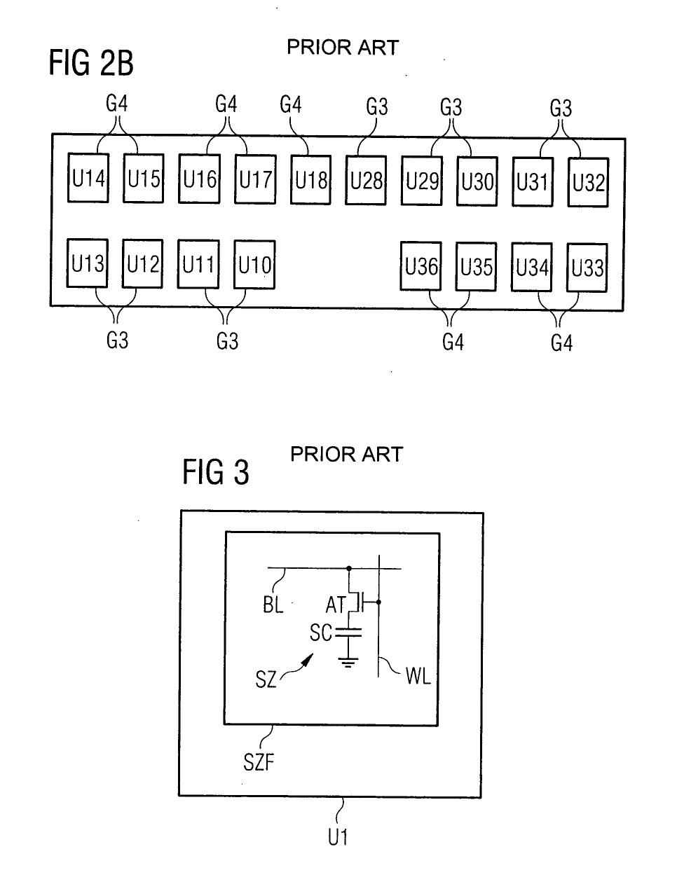

### DETAILED DESCRIPTION

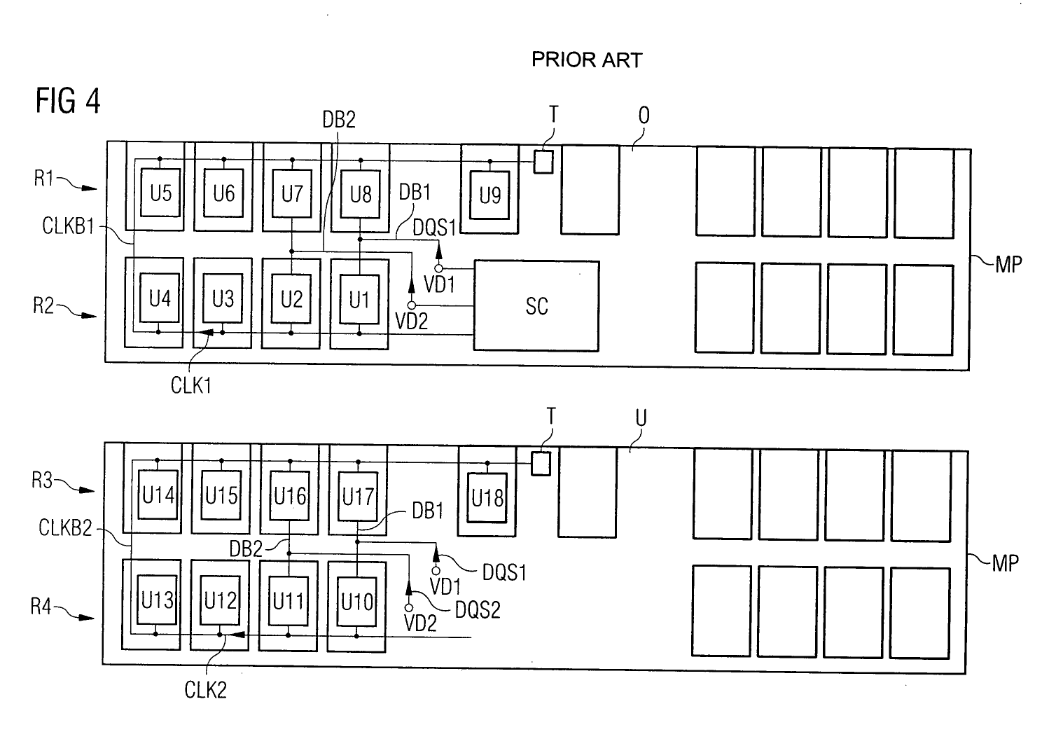

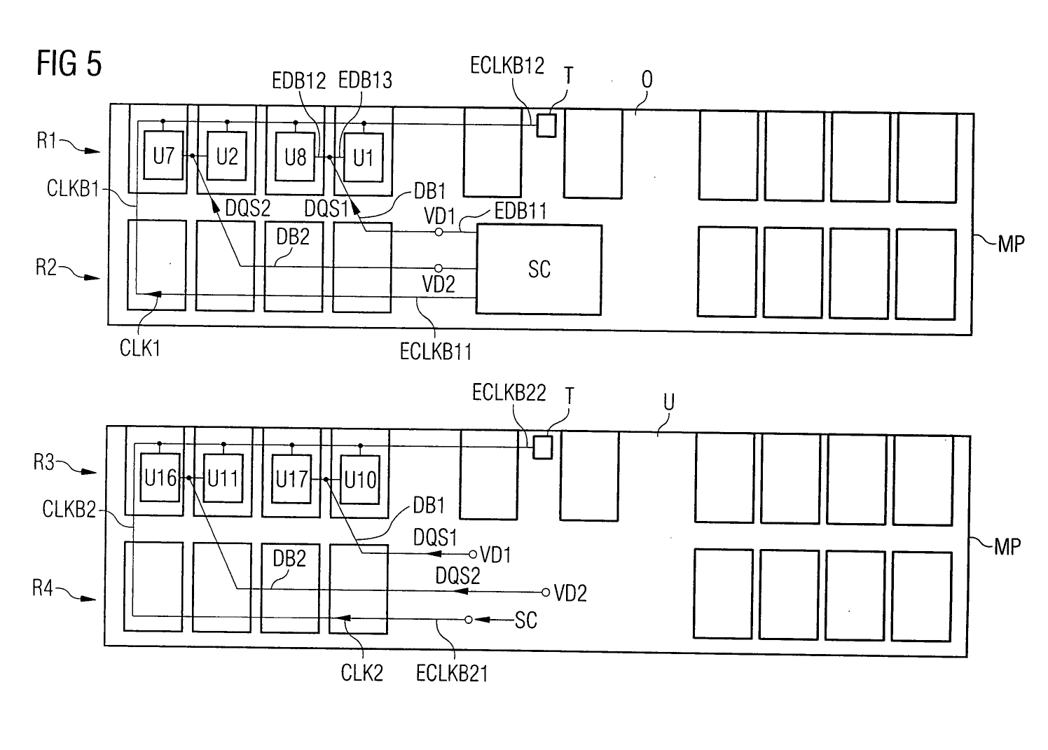

FIG. 5 shows a top side O and an underside U of the module circuit board MP of a semiconductor memory module with an arrangement of memory chips and control and data clock buses in accordance with an embodiment of the invention. For the sake of better clarity, only the memory chips U1 and U2 belonging to the rank G1 and the memory chips U7 and U8 belonging to the rank G2 are illustrated on the top side. Similarly, only the memory chips U10 and U11 belonging to the rank G3 and the memory chips U16 and U17 belonging to the rank G4 are illustrated on the underside of the module circuit board. The control clock buses CLKB1 and CLKB2 for transmitting the control clock signal CLK1 and CLK2 are in each case embodied by a loop fly-by topology as shown in FIG. 4.

The control chip SC is connected to one end ECLKB11 of the control clock bus CLKB1. A terminating impedance T is connected to the other end ECLKB12 of the control clock bus CLKB1. Likewise, one end ECLKB21 of the control clock bus CLKB2 is connected to the control chip SC and another end ECLKB22 of the control clock bus CLKB2 is connected to a terminating impedance T. In contrast to a point-to-point topology, the loop fly-by topology of the control clock buses provides a distinctly better signal integrity of the signals that are transmitted on the control clock buses.

In contrast to the configuration shown in FIG. 4, however, FIG. 5 shows that memory chips belonging to different ranks are arranged alongside one another along the control clock bus CLKB1 and along the control clock bus CLKB2, respectively. Thus, the memory chip U1 of the rank G1 is arranged alongside the memory chip U8 of the rank G2 and the memory chip U2 of the rank G1 is arranged alongside the memory chip U7 of the rank G2. Likewise, the memory chips U10 and U11 of the rank G3 arranged on the underside of the module circuit board are also no longer arranged alongside one another along the control clock bus CLKB2, but rather are in each case arranged alongside the memory chips U16 and U17 of rank G4. Similarly, all further memory chips on the top side and underside of the module circuit board are also likewise no longer arranged alongside one another group by group (rank by rank) in rows. Instead, a memory chip of one rank is arranged in a row alongside a memory chip of another rank.

The data clock buses are embodied in a one-point-to-four-point topology. The control chip SC is connected to one end EDB11 of the data clock bus DB1. At two further ends EDB12 and EDB13 of the data clock bus DB1, the data clock bus DB1 connects the memory chip U1 of the rank G1 and the memory chip U8 of the rank G2 to the control chip SC. Likewise, the data clock bus DB1 on the underside of the module circuit board, at two of its ends, connects the memory chip U10 of the rank G3 and the memory chip U17 of the rank G4 via a contact connecting hole VD1 to the control chip SC on the top side of the circuit board. On the top side of the module circuit board, at two ends of the data clock bus DB2, the latter connects the memory chip U2 of the rank G1 and the memory chip U7 of the rank G2 to the control chip SC. On the underside of the module circuit board, at two ends of the data clock bus DB2, the latter connects the memory chip U11 of the rank G3 and the memory chip U16 of the rank G4 via the contact-connecting hole VD2 to the control chip SC.

In the event of an access to the semiconductor memory module, the control chip accesses all memory chips of a rank simultaneously. Since the bus length of the control clock bus CLKB1 between the control chip and the memory chip U1 of the rank G1 and also between the control chip and the memory chip U8 of the rank G2 is approximately the same, the control clock signal CLK1 reaches memory chips belonging to different ranks at approximately the same time. A small propagation time difference of 400 ps, caused by the control clock signal CLK1 reaching the memory chip U8 slightly before the memory chip U1, can still be tolerated without loss of signal integrity.

The data clock signal DQS1 on the data clock bus DB1 reaches the memory chips U1 and U8 at the same time on account of the same distance between the control chip SC and memory chips U1 and U8. Likewise, the data clock signal DQS2 on the data clock bus DB2, too, reaches the memory chips U2 and U7 at the same time since the bus length of the data clock bus DB2 between the control chip SC and the memory chip U2 is the same as the bus length of the data clock bus DB2 between the control chip SC and the memory chip U7.

On the underside of the module circuit board, the control clock signal CLK2 reaches the memory chips U11 and U16 arranged alongside one another virtually at the same time. The memory chips U17 and U10 arranged alongside one another are addressed by the control clock signal CLK2 slightly later but at virtually the same time. Likewise, the memory chips U10 and U17 are addressed at the same time via the data clock bus DB1 and the memory chips U11 and U16 are addressed at the same time via the data clock bus DB2.

As explained above, the offset between a data clock signal DQS and a control clock signal CLK should not to be greater than 400 ps. The requisite measures are explained below using the example of the memory chips U1 and U8, but can equally also be applied to other pairs of memory chips that are arranged alongside one another and belong to different ranks.

Since the data clock signal DQS1 has the same propagation time from the control chip SC to the memory chips U1 and U8 and the control clock signal CLK1 on the control clock bus CLKB1 likewise has approximately the same propagation time between the control chip SC and the two memory chips U1 and U8, a configuration may be provided for the data clock signal DQS1 and the control clock signal CLK1 to reach the memory chips U1 and U8 approximately at the same time.

One way in which this can be achieved involves adapting the length of the data clock bus DB1 between the control chip SC and the memory chips U1 and U8 to the length of the control clock bus CLKB1 between the control chip SC and the memory chips U1 and U8 such that the control clock signal CLK1 on the control clock bus CLKB1 from the control chip SC as far as the memory chips U1 and U8 has the same propagation time as the data clock signal DQS1 on the data clock bus DB1 between the control chip SC and the two memory chips U1 and U8. Since the signals generally propagate more slowly on a bus with a loop fly-by topology than on a bus having a point-to-point topology, the data clock bus DB1 would therefore have to be made somewhat longer than the length of the control clock bus CLKB1 between the memory chips U1 and U8.

If this is not possible due to a lack of available space, however, in accordance with another variant, the control chip SC is embodied as an intelligent hub chip. The hub chip, in the example of FIG. 5, emits the data clock signal DQS1 temporally delayed with respect to the control clock signal CLK1. If the control clock signal CLK1 on the control clock bus CLKB1 has a propagation time of 1.5 ns, for example, from the control chip SC to the memory chips U1 and U8 and the data clock signal DQS1 on the data clock bus DB1 has a propagation time of approximately 0.4 ns between the control chip SC and the memory chips U1 and U8, then the intelligent hub chip generates the data clock signal DQS1 approximately 1.1 ns after the emission of the control clock signal CLK1. This ensures that the control clock signal CLK1 and the data clock signal DQS1 reach the two memory chips U1 and U8 virtually simultaneously. A small temporal offset between the two signals of approximately 400 ps can be accepted without loss of signal integrity.

Alongside the control clock buses CLKB and the data clock buses DB, the memory chips of a semiconductor memory module are generally also connected to the control chip via a control bus CTRLB and an address bus CAB. Control signals CTRL, such as, by way of example, a chip select signal for selecting a memory chip for a memory access, are transmitted on the control bus CTRLB. While memory chips from different ranks are connected to one of the control clock buses CLKB, memory chips of the same rank are in each case connected to the control bus CTRLB. The control bus CTRLB is thus embodied in a rank-specific manner. Four different control buses exist, therefore, in the case of a module configuration having four ranks.

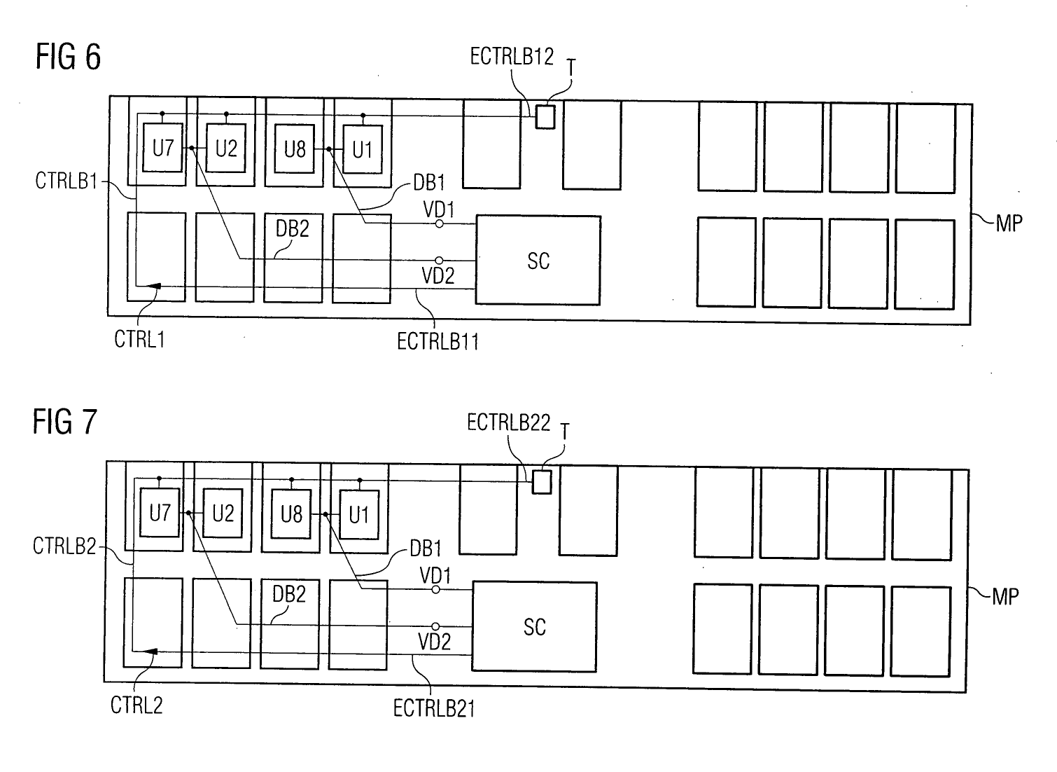

FIGS. 6 and 7 show the memory chips U1 and U8 and also U2 and U7 of the two ranks G1 and G2 arranged alongside one another on the top side of the module circuit board. The memory chips U1 and U8 are connected to the data clock bus DB1. The memory chips U2 and U7 are connected to the data clock bus DB2. In accordance with the embodiment of FIG. 6, the memory chips U1 and U2 belonging to the rank G1 are connected to the control bus CTRLB1 for transmitting the control signal CTRL1. On the other hand, in accordance with the embodiment of FIG. 7, the memory chips U7 and U8 belonging to the rank G2 are connected to the control bus CTRLB2 for transmitting the control signal CTRL2. The control buses CTRLB1 and CTRLB2 are in each case terminated by a terminating impedance T at their respective ends ECTRLB12 and ECTRLB22.

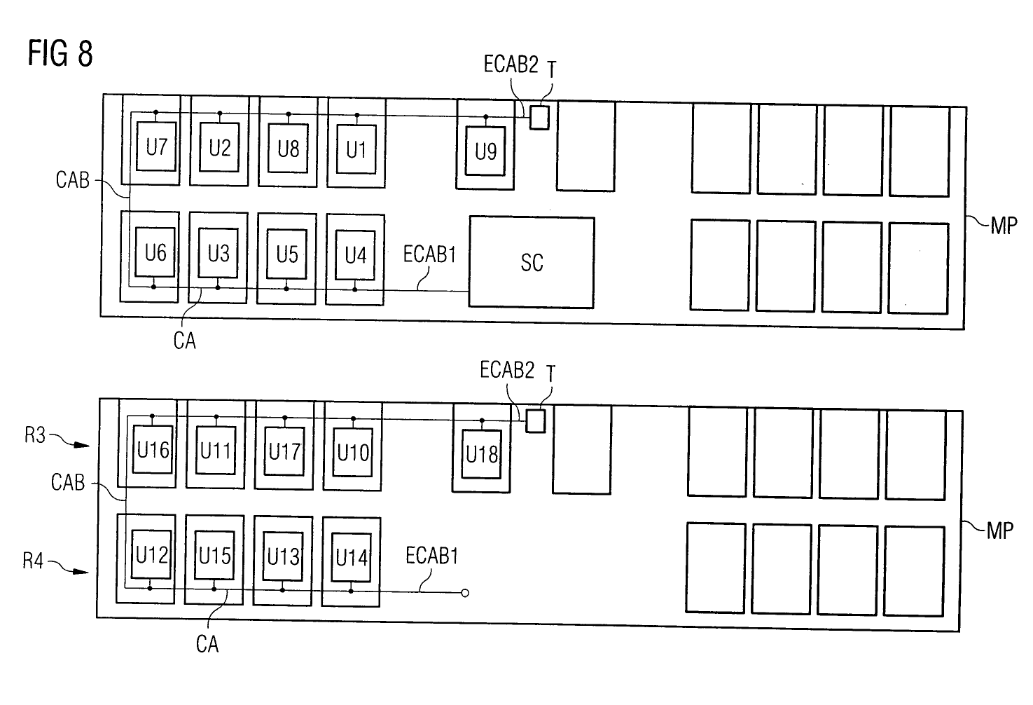

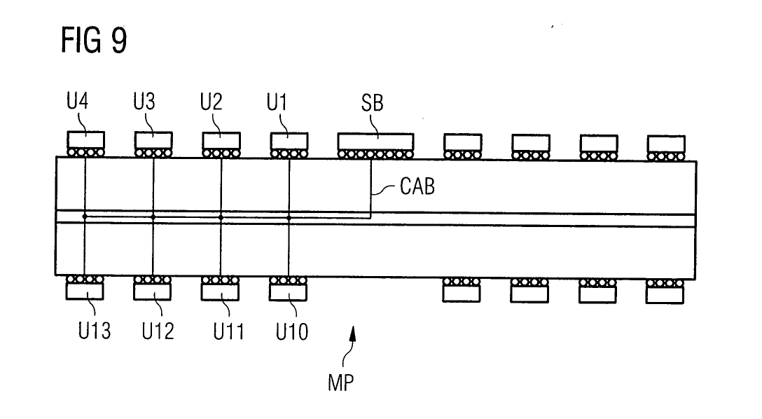

FIGS. 8 and 9 illustrate the connection of the memory chips U1, . . . , U8 on the top side of the module circuit board and of the memory chips U10, . . . , U18 on the underside of the module circuit board to the control bus CAB. The control bus CAB is embodied in accordance with a loop fly-by topology like the control clock buses CLKB1 and CLKB2. The memory chips U1, . . . , U18 on the left-hand side of the module circuit board are connected to the control chip SC via two control clock buses. However, only one address bus CAB is provided for connecting the memory chips U1, . . . , U18 on the left-hand side of the module circuit board to the control chip SC. The memory chips U1, . . . , U18 are arranged along the address bus CAB. The address bus is connected to the control chip SC at one end ECAB1 and terminated by the terminating impedance T at one end ECAB2. Address signals CA that can be used to address individual memory cells within the memory cell array or memory banks are transmitted via the address bus CAB.

The various buses and their control signals may be summarized as follows. The control clock bus CLKB1 is also referred to herein as the first bus, and the control clock signal CLK1 is also referred to herein as the first control signal. Similarly, the data clock bus DB1 is also referred to herein as the second bus, and the data clock signal DQS1 is also referred to herein as the second control signal. The first and second control signals are generated by the control chip and the first signal may be delayed in time with respect to the second control signal.

The memory chips that make up the first rank G1 are also referred to herein as the first group of memory chips and the memory chips that make up the second rank G2 are also referred to herein as the second group of memory chips. The memory chips are arranged on the module circuit board in such a way that memory chips of different ranks are connected to the control clock bus alongside one another.

The first bus (control clock bus) connects the memory chips of the first and second groups to the control chip in a loop fly-by topology, and the second bus (data clock bus) connects memory chips of the first and second groups to the control chip in a point-to-point topology.

The address bus CAB is also referred to herein as the third bus and the address signal CA is also referred to herein as the third control signal. The control bus CTRLB1 is also referred to herein as the fourth bus and the control signal CTRL1 is also referred to as the fourth control signal. Finally, the control bus CTRLB2 is also referred to herein as the fifth bus and the control signal CTRL2 is also referred to herein as the fifth control signal. The fourth and fifth buses are also referred to herein as first and second control buses that transmit first and second control bus signals CTRLB1 and CTRLB2, respectively, to activate first and second group of memory chips, respectively.

The control chip SC is driven by a control component MC via an access bus B that has a data width. The plurality of memory chips may have a common memory array organization and the first and second groups of memory chips may have the same number of memory chips. The number of memory chips in the first and second groups may be dependent on the data width of the access bus and the memory array organization of the memory chips.

The techniques described herein may be employed when the circuit board is a multilayer circuit board, and wherein teach of the first, second, third and fourth buses runs in one of a plurality of layers of the multilayer circuit board.

The foregoing descriptions for the memory chips on the left-hand side of the module circuit board can also be applied to the memory chips on the right-hand side of the module circuit board due to the symmetrical construction of a semiconductor memory module. The configurations described herein of the control and data clock buses and of the address and control buses and also the corresponding arrangement of the memory chips belonging to different ranks on a module circuit board can be used in particular for an FBDIMM (fully buffered dual-in-line memory module) of a 4R×8 and 8R×8 module configuration.

### LIST OF REFERENCE SYMBOLS

MP Module circuit board
L Layer
FBGA Fine pitch ball grid array package
SB Control component
CB Memory component
U Memory chip
SC Control chip
MC Memory controller
B External access bus
SZF Memory cell array
BL Bit line
WL Word line
AT Selection transistor
SC Storage capacitor
SZ Memory cell
DB Data clock bus
DQS Data clock signal
CLKB Control clock bus
CAB Address bus
CLK Control clock signal
CA Address signal
VD, VC Plated-through hole
CTRLB Control bus
CTRL Control signal

What is claimed is:

1. A semiconductor memory module with a bus architecture, comprising:
a module circuit board;
a plurality of memory chips arranged on the module circuit board, said plurality of memory chips comprising a first group of chips and a second group of chips;
a first bus that transmits a first control signal, the first bus having a first end and a second end;
a second bus that transmits a second control signal, the second bus having a first end and at least two second ends; and
a control chip arranged on the module circuit board, wherein the control chip simultaneously accesses memory chips in the first group or the second group, wherein the control chip is connected to the first end of the first bus and to the first end of the second bus;
wherein the plurality of memory chips are connected to the first bus along the first bus between the first end and the second end of the first bus, a respective one of the memory chips in the first group being connected to the first bus alongside a respective one of the memory chips of the second group, one of the memory chips of the first group being connected to one of the second ends of the second bus and one of the memory chips of the second group being connected to another of the second ends of the second bus.

2. The semiconductor memory module of claim 1, wherein the first bus is a control clock bus that transmits the first control signal, and wherein the first control signal is a control clock signal, and wherein a read and write access to the first or second groups of memory chips of is executed synchronously with the control clock signal.

3. The semiconductor memory module of claim 2, wherein the second bus is a data clock bus that transmits the second control signal, wherein the second control signal is a data clock signal, and wherein in the event of a read access to the first or second groups of memory chips, data are read out from the first or second groups of memory chips synchronously with the data clock signal, and in the event of a write access to the first or second groups of memory chips, data are written to the first or second groups of memory chips synchronously with the data clock signal.

4. The semiconductor memory module of claim 3, and further comprising a third bus that transmits a third control signal, the third bus having a first end and a second end, wherein the control chip is connected to the first end of the third bus and the plurality of memory chips are connected to the third bus along the third bus between the first end and the second end of the third bus, a respective one of the memory chips of the first group being connected to the third bus alongside a respective one of the memory chips of the second group.

5. The semiconductor memory module of claim 4, wherein the third bus is as an address bus that transmits the third control signal, and wherein the third control signal is an address signal.

6. The semiconductor memory module of claim 5, and further comprising a fourth bus that transmits a fourth control signal, the fourth bus having a first end and a second end, wherein the control chip is connected to the first end of the fourth bus and the first group of memory chips being connected to the fourth bus along the fourth bus between the first end and the second end of the fourth bus, wherein the first group of memory chips being arranged alongside one another along the fourth bus.

7. The semiconductor memory module of claim 6, wherein the module circuit board is a multilayer circuit board comprising a plurality of layers, and wherein each of the first, second, third and fourth buses runs in one of the plurality of layers of the multilayer circuit board.

8. The semiconductor memory module of claim 6, and further comprising a fifth bus that transmits a fifth control signal, the fifth bus having a first end and a second end, wherein the control chip is connected to the first end of the fifth bus and the second group of memory chips being connected to the fifth bus along the fifth bus between the first end and the second end of the fifth bus, and wherein the second group of memory chips being arranged alongside one another along the fifth bus.

9. The semiconductor memory module of claim 9, wherein the fourth bus and the fifth bus are each a control bus that activates the first and second group of memory chips, respectively, for a read and a write access.

10. The semiconductor memory module of claim 9, and further comprising a terminating impedance that terminates the second end of the first bus, the second end of the third bus, the second of the fourth bus and the second end of the fifth bus.

11. The semiconductor memory module of claim 1, wherein the first and second groups of memory chips are arranged in at least one row on a surface of the module circuit board, and wherein within the row a respective one of the memory chips of the first group is arranged alongside a respective one of the memory chips of the second group.

12. The semiconductor memory module of claim 1, wherein each of the memory chips comprises a memory cell array comprising dynamic random access memory cells.

13. The semiconductor memory module of claim 1, wherein the control chip is a hub chip.

14. The semiconductor memory module of claim 13, wherein the hub chip generates the first control signal and the second control signal, and wherein the first control signal is delayed with respect to the second control signal.

15. The semiconductor memory module of claim 1, wherein the module circuit board is a multilayer circuit board.

16. The semiconductor memory module of claim 1, wherein the plurality of memory chips and the control chip are arranged in a fine pitch ball grid array package on the module circuit board.

17. The semiconductor memory module of claim 1, wherein the control chip is driven by a control component via an access bus having a data width, the plurality of memory chips have common memory array organization, the first and second groups of memory chips comprises the same number of memory chips, and the number of memory chips in the first and second groups is dependent on the data width of the access bus and the memory array organization of the memory chips.

18. The semiconductor memory module of claim 1, wherein the memory chips of the first group form a first rank and the memory chips of the second group form a second rank.

19. The semiconductor memory module of claim 1, wherein the semiconductor memory module has a 4R×8 configuration.

20. The semiconductor memory module of claim 1, wherein the semiconductor memory module has an 8R×8 configuration.

21. The semiconductor memory module of claim 1, wherein the plurality of memory chips are arranged on the module circuit board so that as to form a dual-in-line memory module.

22. A semiconductor memory module with a bus architecture, comprising:
a circuit board;
a plurality of memory chips on the circuit board, said plurality of memory chips comprising at least a first group of chips and a second group of chips;
a first bus that transmits a first control signal;
a second bus that transmits a second control signal; and
a control chip on the circuit board, wherein the control chip simultaneously accesses memory chips in the first group or the second group, wherein the control chip is connected to the first bus and the second bus;
wherein the plurality of memory chips are connected to the first bus along a length thereof, a respective one of the memory chips in the first group being connected to the first bus alongside a respective one of the memory chips of the second group.

23. The semiconductor memory module of claim 22, wherein the first bus is a control clock bus that transmits the first control signal, wherein the first control signal is a clock control signal, wherein a read and write access to the first or second groups of memory chips of is executed synchronously with the control clock signal, and wherein the second bus is a data clock bus that transmits the second control signal, wherein the second control signal is a data clock signal, wherein in the event of a read access to the first or second groups of memory chips, data are read out from the first or second groups of memory chips synchronously with the data clock signal, and in the event of a write access to the first or second groups of memory chips, data are written to the first or second groups of memory chips synchronously with the data clock signal.

24. The semiconductor memory module of claim 23, and further comprising a third bus that is an address bus that transmits an address signal, wherein the control chip is connected to the third bus, a respective one of the memory chips of the first group being connected to the third bus alongside a respective one of the memory chips of the second group.

25. The semiconductor memory module of claim 24, and further comprising first and second control buses that transmit first and second control bus signals, respectively, wherein the control chip is connected to the first control bus and the second control bus, the first group of memory chips being connected to the first control bus along a length thereof and alongside one another along the first control bus, wherein the second group of memory chips being connected to the second control bus along a length thereof and arranged alongside one another along the second control bus.

26. The semiconductor memory module of claim 22, wherein the first and second groups of memory chips are arranged in at least one row on a surface of the circuit board, and wherein within the row a respective one of the memory chips of the first group is arranged alongside a respective one of the memory chips of the second group.

27. The semiconductor memory module of claim 22, wherein the first bus is a control clock bus and connects the memory chips of the first and second groups to the control chip in a loop fly-by topology, and wherein the second bus is a data clock bus that connects memory chips of the first and second groups to the control chip in a point-to-point topology.

28. A semiconductor memory module with a bus architecture, comprising:
a circuit board;
a plurality of memory chips on the circuit board, said plurality of memory chips comprising at least a first group of chips and a second group of chips;
clock bus means for transmitting a clock signal;
data bus means for transmitting a data signal; and
control means on the circuit board that simultaneously accesses memory chips in the first group or the second group;
wherein the plurality of memory chips are connected to the clock bus means along a length thereof, a respective one of the memory chips in the first group being connected to the clock bus means alongside a respective one of the memory chips of the second group.
